(19) United States
(12) Patent Application Publication
(10) Pub. No.: US 2012/0081638 A1
(43) Pub. Date: Apr. 5, 2012

(54) LIGHT SENSING ELEMENT, SEMICONDUCTOR DEVICE, ELECTRONIC EQUIPMENT, MANUFACTURING METHOD OF LIGHT SENSING ELEMENT, AND MANUFACTURING METHOD OF SEMICONDUCTOR DEVICE

(75) Inventors: Hiroshi Yumoto, Kagoshima (JP); Shuji Yoneda, Kagoshima (JP); Yusuke Murakawa, Kagoshima (JP); Hideo Yamagata, Kagoshima (JP)

(73) Assignee: SONY CORPORATION, Tokyo (JP)

(21) Appl. No.: 13/242,416

(22) Filed: Sep. 23, 2011

(30) Foreign Application Priority Data
Oct. 4, 2010 (JP) 2010-225011

(51) Int. Cl. G02F 1/1333; G01J 1/44; H01L 31/18; H01L 31/102

(52) U.S. Cl. 349/84; 257/461; 250/208.2; 438/57; 438/73; 257/E31.055

(57) ABSTRACT

A light sensing element includes a photodiode formed on a semiconductor substrate surface, and a laminated structure formed on the photodiode, wherein the laminated structure includes a first layer formed of a silicon oxide film, a second layer formed on the first layer and formed of a silicon nitride film, and a third layer formed on the second layer and formed of a polysilicon film.

### BACKGROUND

The present disclosure relates to a light sensing element, a semiconductor device, electronic equipment, a manufacturing method of the light sensing element, and a manufacturing method of the semiconductor device.

In the related art, in a semiconductor device, for example, a mobile phone having a liquid crystal display panel, ambient light is measured using a light sensor at the time of opening and closing (including sliding). The light sensor has a function of detecting external brightness, and adjusting a current output to LEDs used for a backlight of the liquid crystal display panel based on the detected value. In addition, in a case where the mobile phone or the like having the liquid crystal display panel is provided with a proximity sensor, if the face of a user is close to the liquid crystal display panel while talking, the backlight of the liquid crystal display panel is turned off, which thus contributes to energy conservation of an internal battery. On the other hand, if talking is completed and the face of the user becomes distant from the liquid crystal display panel, the backlight of the liquid crystal display panel is turned on, and the user can view the liquid crystal display panel.

In order to appropriately realize the function using the measured value, the sensitivity of the light sensor measuring ambient light can be made to correspond to human sensitivity to light and darkness by being set using a human visual sensitivity characteristic as a reference. For example, in a case of adjusting luminance of the liquid crystal display panel with respect to ambient light, the human visual sensitivity characteristic is used as a reference, and viewing easiness is improved by adjusting the luminance so as to be close to the human visual sensitivity characteristic.

For this reason, for example, there is a technique in which two photodiodes formed in parallel on the same substrate are used, a color filter having a bandpass filter function of transmitting different wavelengths of light beams from the respective photodiodes therethrough is mounted, and closeness to the visual sensitivity characteristic is performed by calculating a difference between the respective outputs (for example, refer to Japanese Unexamined Patent Application Publication No. 2007-227551). In addition, there is another technique in which two photodiodes having different depths are formed on the same substrate, and closeness to the visual sensitivity characteristic is performed by calculating a difference between the respective outputs (for example, refer to Japanese Unexamined Patent Application Publication No. 2007-305868).

There is a technique in which a first photodiode and a second photodiode which are formed in parallel on the same substrate are provided, and a difference between outputs from the first photodiode and the second photodiode is calculated (for example, refer to Japanese Unexamined Patent Application Publication No. 2006-351616). In this technique, the second photodiode includes a laminated structure, and the laminated structure has a first layer formed of a silicon oxide film, a second layer formed on the first layer and formed of a polysilicon film, and a third layer formed on the second layer and formed of the silicon oxide film.

### SUMMARY

However, in a case of using the color filter, there is a problem in that the number of processes increases, and development costs of color filters for obtaining desired spectral sensitivity also increase. In addition, since the color filter is disposed to be spaced upwardly from a surface portion of the photodiode, for example, with an interlayered insulating film interposed therebetween, there is a possibility that the reflectance or the attenuation ratio of the overall light sensing portion may vary with respect to obliquely incident light, or incident light may reach the photodiode via the color filter. For this reason, there is a problem in that the spectral sensitivity characteristic is difficult to stabilize, difference between products easily occurs, a characteristic close to the visual sensitivity characteristic is difficult to secure, and thus a degree of freedom of a design is lowered.

In addition, in a case of using the photodiodes having different depths, there are problems in that it is necessary to form a plurality of impurity diffusion layers in a silicon substrate, which thus leads to increases in the number of processes and costs, and a spectral sensitivity characteristic imbalance becomes great since it is difficult to form depths of the diffusion layers and the concentration of the impurity to be stable for adjusting spectral sensitivity.

Further, in the technique disclosed in Japanese Unexamined Patent Application Publication No. 2006-351616, there is a problem in that a range where the spectral sensitivity characteristic is freely set is narrow, and it is difficult to approach the visual sensitivity characteristic.

It is desirable to provide a light sensing element, a semiconductor device, electronic equipment, a manufacturing method of the light sensing element, and a manufacturing method of the semiconductor device, capable of reducing a difference in products through contribution to stabilization of a spectral sensitivity characteristic, and improving a degree of freedom of a design by easily securing a characteristic close to a visual sensitivity characteristic.

According to an embodiment of the present disclosure, there is provided a light sensing element including a photodiode formed on a semiconductor substrate surface; and a laminated structure formed on the photodiode, wherein the laminated structure includes a first layer formed of a silicon oxide film; a second layer formed on the first layer and formed of a silicon nitride film; and a third layer formed on the second layer and formed of a polysilicon film.

In this case, the laminated structure may further include a fourth layer formed on the third layer and formed of a polycrystalline silicon and germanium film.

According to another embodiment of the present disclosure, there is provided a light sensing element including a photodiode formed on a semiconductor substrate surface; and a laminated structure formed on the photodiode, wherein the laminated structure includes a first layer formed of a silicon oxide film; a second layer formed on the first layer and formed of a silicon nitride film; and a third layer formed on the second layer and formed of a polycrystalline silicon and germanium film.

According to still another embodiment of the present disclosure, there is provided a semiconductor device including a first photodiode, a second photodiode, and a third photodiode, formed on a semiconductor substrate surface; a first laminated structure formed on the first photodiode; a second laminated structure formed on the second photodiode; a third laminated structure formed on the third photodiode; a first calculation circuit calculating a difference between outputs from the first photodiode and the third photodiode; and a second calculation circuit calculating a difference between outputs from the first photodiode and the second photodiode, wherein the first laminated structure includes a first layer formed of a silicon oxide film; a second layer formed on the first layer and formed of a silicon nitride film; and a third layer formed on the second layer and formed of a polysilicon film, wherein the second laminated structure includes a first layer formed of the silicon oxide film; a second layer formed on the first layer and formed of the silicon nitride film; and a third layer formed on the second layer and formed of a polycrystalline silicon and germanium film, and wherein the third laminated structure includes a first layer formed of a silicon oxide film; a second layer formed on the first layer and formed of a silicon nitride film; a third layer formed on the second layer and formed of the polysilicon film; and a fourth layer formed on the third layer and formed of the polycrystalline silicon and germanium film.

According to still another embodiment of the present disclosure, there is provided a semiconductor device including a first photodiode and a second photodiode formed on a semiconductor substrate surface; a first laminated structure formed on the first photodiode; a second laminated structure formed on the second photodiode; and a calculation circuit calculating a difference between outputs from the first photodiode and the second photodiode, wherein the first laminated structure includes a first layer formed of a silicon oxide film; a second layer formed on the first layer and formed of a silicon nitride film; and a third layer formed on the second layer and formed of a polysilicon film, and wherein the second laminated structure includes a first layer formed of the silicon oxide film; a second layer formed on the first layer and formed of the silicon nitride film; and a third layer formed on the second layer and formed of a polycrystalline silicon and germanium film.

According to still another embodiment, there is provided electronic equipment including a first photodiode, a second photodiode, and a third photodiode, formed on a semiconductor substrate surface; a first laminated structure formed on the first photodiode; a second laminated structure formed on the second photodiode; a third laminated structure formed on the third photodiode; a first calculation circuit calculating a difference between outputs from the first photodiode and the third photodiode; a second calculation circuit calculating a difference between outputs from the first photodiode and the second photodiode; a liquid crystal display panel; and a control circuit adjusting luminance of the liquid crystal display panel based on a calculation result of the first calculation circuit, and powering on and off a backlight of the liquid crystal display panel based on a calculation result of the second calculation circuit, wherein the first laminated structure includes a first layer formed of a silicon oxide film; a second layer formed on the first layer and formed of a silicon nitride film; and a third layer formed on the second layer and formed of a polysilicon film, wherein the second laminated structure includes a first layer formed of the silicon oxide film; a second layer formed on the first layer and formed of the silicon nitride film; and a third layer formed on the second layer and formed of a polycrystalline silicon and germanium film, and wherein the third laminated structure includes a first layer formed of the silicon oxide film; a second layer formed on the first layer and formed of the silicon nitride film; a third layer formed on the second layer and formed of the polysilicon film; and a fourth layer formed on the third layer and formed of the polycrystalline silicon and germanium film.

According to still another embodiment of the present disclosure, there is provided electronic equipment including a first photodiode and a second photodiode formed on a semiconductor substrate surface; a first laminated structure formed on the first photodiode; a second laminated structure formed on the second photodiode; a calculation circuit calculating a difference between outputs from the first photodiode and the second photodiode; a liquid crystal display panel; and a control circuit adjusting luminance of the liquid crystal display panel based on a calculation result of the calculation circuit, wherein the first laminated structure includes a first layer formed of a silicon oxide film; a second layer formed on the first layer and formed of a silicon nitride film; and a third layer formed on the second layer and formed of a polysilicon film, and wherein the second laminated structure includes a first layer formed of the silicon oxide film; a second layer formed on the first layer and formed of the silicon nitride film; and a third layer formed on the second layer and formed of a polycrystalline silicon and germanium film.

According to still another embodiment of the present disclosure, there is provided a manufacturing method of a light sensing element including forming a photodiode on a semiconductor substrate; forming a silicon oxide film on the photodiode; forming a silicon nitride film on the silicon oxide film; and forming a polysilicon film on the silicon nitride film.

The manufacturing method of the light sensing element may further include forming a polycrystalline silicon and germanium film on the polysilicon film.

According to still another embodiment of the present disclosure, there is provided a manufacturing method of a light sensing element including forming a photodiode on a semiconductor substrate; forming a silicon oxide film on the photodiode; forming a silicon nitride film on the silicon oxide film; and forming a polycrystalline silicon and germanium film on the silicon nitride film.

According to still another embodiment of the present disclosure, there is provided a manufacturing method of a semiconductor device including forming a first photodiode, a second photodiode, and a third photodiode on a semiconductor substrate; forming a silicon oxide film on the first photodiode, the second photodiode, and the third photodiode; forming a silicon nitride film on the silicon oxide film; forming a polysilicon film on the silicon nitride film of the first photodiode and the third photodiode; and forming a polycrystalline silicon and germanium film on the polysilicon film of the third photodiode and forming the polycrystalline silicon and germanium film on the silicon nitride film of the second photodiode.

According to still another embodiment of the present disclosure, there is a manufacturing method of a semiconductor device including forming a first photodiode and a second photodiode on a semiconductor substrate; forming a silicon oxide film on the first photodiode and the second photodiode; forming a silicon nitride film on the silicon oxide film; forming a polysilicon film on the silicon nitride film of the first photodiode; and forming a polycrystalline silicon and germanium film on the silicon nitride film of the second photodiode.

According to the light sensing element of the present disclosure, it is possible to obtain a desired spectral sensitivity characteristic, and, for example, to obtain a spectral sensitivity characteristic close to a visual sensitivity characteristic or a spectral sensitivity characteristic having a peak in an infrared region.

In addition, according to the semiconductor device of the present disclosure, it is possible to reduce difference in products through contribution to stabilization of a spectral sensitivity characteristic, and improve a degree of freedom of a design by easily securing a characteristic close to a visual sensitivity characteristic or a characteristic having a peak in an infrared region.

In addition, according to the electronic equipment of the present disclosure, it is possible to reduce difference in products through contribution to stabilization of a spectral sensitivity characteristic, and improve a degree of freedom of a design by easily securing a characteristic close to a visual sensitivity characteristic or a characteristic having a peak in an infrared region.

### BRIEF DESCRIPTION OF THE DRAWINGS

FIGS. 1A to 1C are diagrams illustrating a cross-sectional configuration of a laminated structure in a light sensing element according to a first embodiment of the present disclosure.

FIG. 2 is a diagram illustrating a relationship between a wavelength of light incident to a polycrystalline silicon and germanium film and a refractive index thereof.

FIG. 3 is a diagram illustrating a relationship between a wavelength of light incident to a polycrystalline silicon and germanium film and an extinction coefficient thereof.

FIG. 4 is a schematic diagram illustrating a cross-sectional configuration of main parts of a semiconductor device according to the first embodiment of the present disclosure.

FIG. 5 is a diagram illustrating a circuit configuration of the semiconductor device according to the first embodiment of the present disclosure.

FIG. 6 is a diagram illustrating a spectral sensitivity characteristic after calculation (subtraction) in a case of using a first photodiode and a third photodiode in a light sensor.

FIG. 7 is a diagram illustrating a spectral sensitivity characteristic after calculation (subtraction) in a case of using a first photodiode and a second photodiode in a proximity sensor.

FIG. 8 is a front view of electronic equipment to which the semiconductor device according to the first embodiment of the present disclosure is applied.

FIG. 9A is a cross-sectional view of main parts in manufacturing procedures in the semiconductor device according to the first embodiment of the present disclosure.

FIG. 9B is a diagram subsequent to FIG. 9A.

FIG. 9C is a diagram subsequent to FIG. 9B.

FIG. 9D is a diagram subsequent to FIG. 9C.

FIG. 9E is a diagram subsequent to FIG. 9D.

FIG. 9F is a diagram subsequent to FIG. 9E.

FIG. 9G is a diagram subsequent to FIG. 9F.

FIG. 9H is a diagram subsequent to FIG. 9G.

FIG. 9I is a diagram subsequent to FIG. 9H.

FIG. 9J is a diagram subsequent to FIG. 9I.

FIG. 9K is a diagram subsequent to FIG. 9J.

FIG. 9L is a diagram subsequent to FIG. 9K.

FIG. 9M is a diagram subsequent to FIG. 9L.

FIGS. 10A and 10B are diagrams illustrating a cross-sectional configuration of a laminated structure in a light sensing element according to a second embodiment of the present disclosure.

FIG. 11 is a schematic diagram illustrating a cross-sectional configuration of main parts of a semiconductor device according to the second embodiment of the present disclosure.

FIG. 12 is a diagram illustrating a circuit configuration of the semiconductor device according to the second embodiment of the present disclosure.

FIG. 13 is a diagram illustrating a spectral sensitivity characteristic after calculation (subtraction) in a case of using a first photodiode and a second photodiode in a light sensor.

FIG. 14A is a diagram illustrating manufacturing steps of main parts of the semiconductor device according to the second embodiment of the present disclosure.

FIG. 14B is a diagram subsequent to FIG. 14A.

FIG. 14C is a diagram subsequent to FIG. 14B.

FIG. 14D is a diagram subsequent to FIG. 14C.

FIG. 14E is a diagram subsequent to FIG. 14D.

### DETAILED DESCRIPTION OF EMBODIMENTS

A light sensing element, a semiconductor device, electronic equipment, a manufacturing method of the light sensing element, and a manufacturing method of the semiconductor device according to an embodiment will be described with reference to the drawings. In addition, embodiments described below are preferred detailed examples in a manufacturing method of a semiconductor device, and various preferable limitations are given in a technical sense, but a technical scope of the present disclosure is not limited to such a form as long as there is no description limiting the present disclosure. In addition, constituent elements in the embodiments described below may be appropriately replaced with existing constituent elements, and further a variety of variations including combinations with other existing constituent elements are possible. Therefore, description of the embodiments shown below does not limit content of the present disclosure recited in the claims.

### First Embodiment

A semiconductor device according to the embodiment will be described. The semiconductor device according to the embodiment includes a light sensor and a proximity sensor formed on a semiconductor substrate.

The light sensor is a sensor detecting brightness, and includes a first light sensing element and a third light sensing element, having different optical characteristics such as a refractive index or an extinction coefficient, and a first calculation circuit calculating (subtracting) outputs from the first light sensing element and the third light sensing element. In addition, the proximity sensor is a sensor detecting presence or absence of an object from an amount of light which strikes and is reflected by the object using infrared rays, and includes the first light sensing element and a second light sensing element having the different optical characteristics and a second calculation circuit calculating (subtracting) outputs from the first light sensing element and the second light sensing element.

The first light sensing element includes a first photodiode formed on a surface of a semiconductor substrate, and a first laminated structure formed on the first photodiode, and optical characteristics of the first light sensing element are set by a layer configuration of the first laminated structure. The second light sensing element includes a second photodiode formed on the surface of the semiconductor substrate, and a second laminated structure formed on the second photodiode, and optical characteristics of the second light sensing element are set by a layer configuration of the second laminated structure. In addition, the third light sensing element includes a third photodiode formed on the surface of the semiconductor substrate, and a third laminated structure formed on the third photodiode, and optical characteristics of the third light sensing element are set by a layer configuration of the third laminated structure.

In the embodiment, it is possible to give desired optical characteristics to the first to third light sensing elements depending on materials, film thicknesses or composition ratios of the respective first to third laminated structures, and thereby a spectral sensitivity characteristic of the light sensor approaches the visual sensitivity characteristic, and a spectral sensitivity characteristic of the proximity sensor has a peak value in an infrared range.

Hereinafter, a light sensing element, a semiconductor device having the light sensing element, and electronic equipment having the semiconductor device according to the first embodiment of the present disclosure will be described in detail with reference to the drawings. In addition, the description will be made in the following order.

1. LIGHT SENSING ELEMENT ACCORDING TO FIRST EMBODIMENT

2. SEMICONDUCTOR DEVICE ACCORDING TO FIRST EMBODIMENT

3. ELECTRONIC EQUIPMENT ACCORDING TO FIRST EMBODIMENT

4. MANUFACTURING METHOD OF SEMICONDUCTOR DEVICE ACCORDING TO FIRST EMBODIMENT

### 1. Light Sensing Element According to First Embodiment

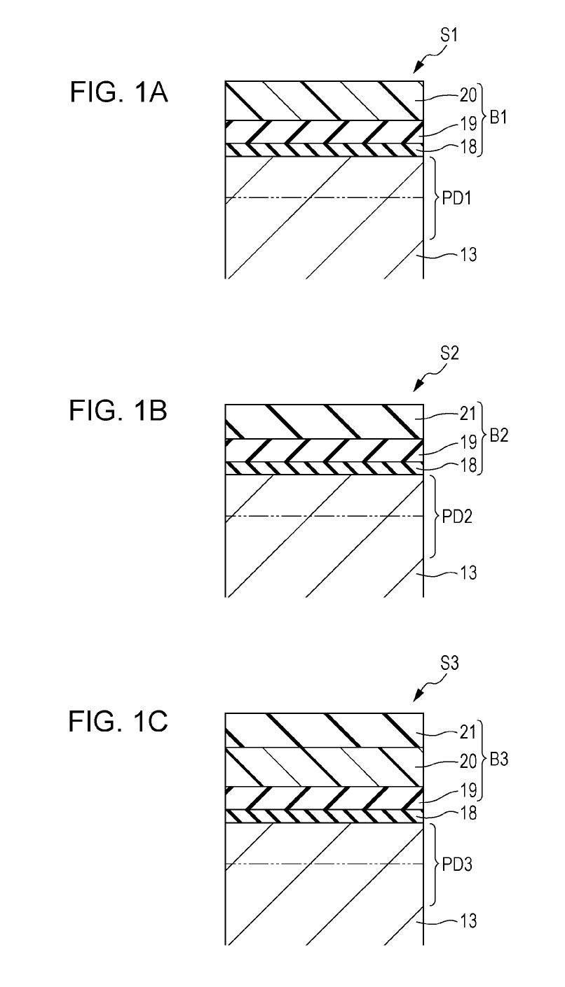

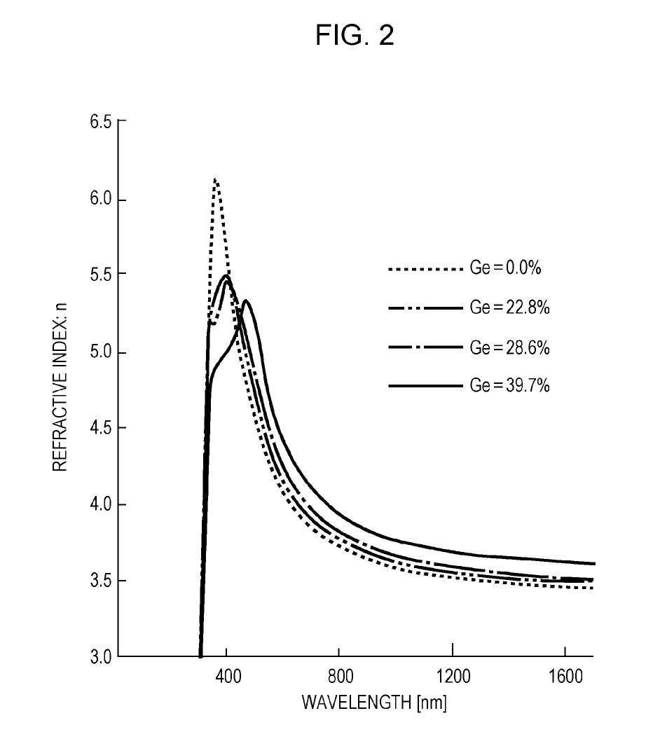

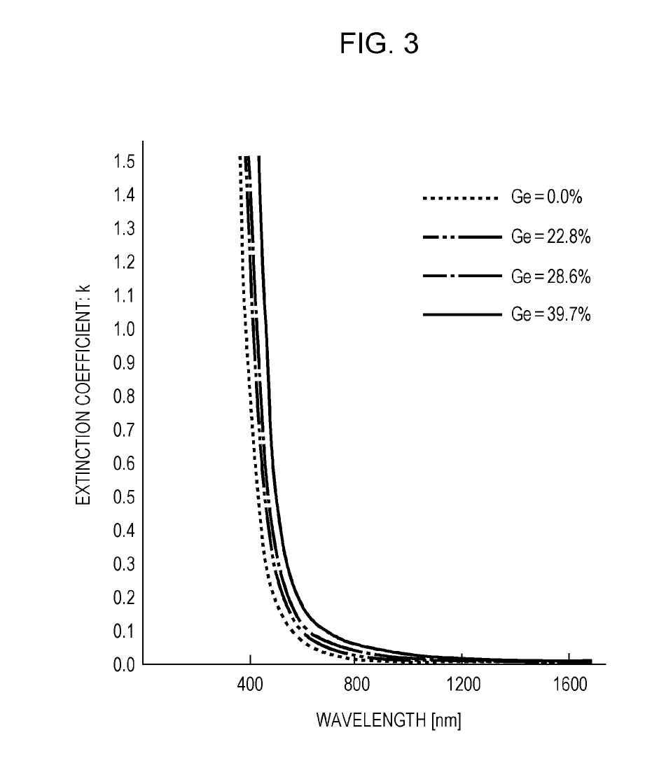

The light sensing element according to the embodiment includes a photodiode formed on a surface of a semiconductor substrate and a laminated structure formed on the photodiode and functioning as an optical filter, so as to obtain a desired optical characteristic (a refractive index, an extinction coefficient, or the like). Hereinafter, the light sensing element according to the embodiment will be described with reference to the drawings. FIGS. 1A to 1C are diagrams illustrating cross-sectional configurations of laminated structures in the light sensing elements according to the embodiment. FIG. 1A is a diagram illustrating a configuration of a first light sensing element S1; FIG. 1B is a diagram illustrating a configuration of a second light sensing element S2; and FIG. 1C is a diagram illustrating a configuration of a third light sensing element S3.

As shown in FIG. 1A, the first light sensing element S1 includes a first photodiode PD1 formed on a surface of, for example, a P type semiconductor substrate 13 such as silicon (Si), doped with a P impurity such as boron (B), and a first laminated structure B1 formed on the first photodiode PD1.

The first laminated structure B1 has a first layer 18 formed on the first photodiode PD1 and formed of a silicon oxide film, a second layer 19 formed on the first layer 18 and formed of a silicon nitride film, and a third layer 20 formed on the second layer 19 and formed of a polysilicon film.

The film thickness of the silicon oxide film as the first layer 18 is between, for example, 5 nm and 40 nm, and, preferably, between 10 nm and 30 nm. For example, in a case where the film thickness is 5 nm or less, there is a problem in that an influence on spectral sensitivity increases by an amount corresponding to a difference in the film thickness. In addition, in a case where the film thickness is 40 nm or more, there is a problem in that spectral sensitivity controllability is deteriorated because interference with an overlying film or a multiple reflection effect increases. In the embodiment, the film thickness of the silicon oxide film as the first layer 18 is 12 nm.

The film thickness of the silicon nitride film as the second layer 19 is between, for example, 10 nm and 60 nm, and, preferably, between 15 nm and 40 nm. For example, in a case where the film thickness is 10 nm or less, there is a problem in that influence on spectral sensitivity increases by an amount corresponding to a difference in the film thickness. In addition, in a case where the film thickness is 60 nm or more, there is a problem in that spectral sensitivity controllability is deteriorated because interference with an overlying film or a multiple reflection effect increases. In the embodiment, the film thickness of the silicon nitride film as the second layer 19 is 20 nm.

In addition, the film thickness of the polysilicon film as the third layer 20 is between, for example, 20 nm and 100 nm, and, preferably, between 30 nm and 80 nm. For example, in a case where the film thickness is 20 nm or less, there is a problem in that uniformity of the film thickness is deteriorated, and the spectral sensitivity is irregular. In addition, in a case where the film thickness is 100 nm or more, there is a problem in that manufacturing costs increase. In the embodiment, the film thickness of the polysilicon film as the third layer 20 is 33 nm.

Next, as shown in FIG. 1B, the second light sensing element S2 includes a second photodiode PD2 formed on the surface of the P type semiconductor substrate 13 and a second laminated structure B2 formed on the second photodiode PD2.

The second laminated structure B2 has the first layer 18 formed on the second photodiode PD2 and formed of the silicon oxide film, the second layer 19 formed on the first layer 18 and formed of the silicon nitride film, and a third layer 21 formed on the second layer 19 and formed of a polycrystalline silicon and germanium film. The same configurations as the above-described first laminated structure B1 are given the same reference numerals, and description thereof will be omitted.

The film thickness of the polycrystalline silicon and germanium film as the third layer 21 is, for example, between 20 nm and 120 nm, and, preferably, between 25 nm and 100 nm. For example, in a case where the film thickness is 20 nm or less, there is a problem in that composition controllability of germanium is deteriorated, and the spectral sensitivity is irregular. In addition, in a case where the film thickness is 120 nm or more, there is a problem in that manufacturing costs increase. In the embodiment, the film thickness of the polycrystalline silicon and germanium film as the third layer 21 is 30 nm.

Further, a composition ratio of germanium is between 35 and 55%. Preferably, concentration of germanium ranges from 40% to 50%. In a case where germanium is 35% or less, a difference of a value of the refractive index n and a value of the extinction coefficient k from those in a case of using a polysilicon film on the uppermost layer of the laminated structure is slight, and it is difficult to correct the spectral sensitivity. In addition, in a case where germanium is 55% or more, there is a problem in that surface roughness of the silicon and germanium film is deteriorated, which has influence on optical characteristics. In the embodiment, the composition ratio of germanium is 39.7%.

Next, as shown in FIG. 1C, the third light sensing element S3 includes a third photodiode PD3 formed on the surface of the P type semiconductor substrate 13 and a third laminated structure B3 formed on the third photodiode PD3.

The third laminated structure B3 has the first layer 18 formed on the third photodiode PD3 and formed of the silicon oxide film, the second layer 19 formed on the first layer 18 and formed of the silicon nitride film, and the third layer 20 formed on the second layer 19 and formed of the polysilicon film, and a fourth layer formed on the third layer 20 and formed of the polycrystalline silicon and germanium film. The films forming the third laminated structure B3 are the same as the films forming the first laminated structure B1 or the second laminated structure B2, which are thus given the same reference numerals, and description thereof will be omitted.

The third light sensing element S3 has the above-described configuration of the third laminated structure B3, and thus it is possible to obtain a spectral sensitivity characteristic having a peak value in a desired wavelength range.

### 2. Semiconductor Device According to First Embodiment

Next, the semiconductor device according to the embodiment will be described. The semiconductor device according to the embodiment includes a light sensor detecting light of surrounding environments, and a proximity sensor detecting touching or approaching of an object, and the light sensor and the proximity sensor are formed on the same semiconductor substrate. The light sensor includes the first light sensing element S1 and the third light sensing element S3 described above, and an operational amplifier (calculation circuit) described later, and the proximity sensor includes the first light sensing element S1 and the second light sensing element S2 described above, and an operational amplifier (calculation circuit). In the semiconductor device according to the embodiment, a spectral sensitivity characteristic of the light sensor approaches the human visual sensitivity characteristic with respect to brightness, and a spectral sensitivity characteristic of the proximity sensor has a peak value in the infrared range.

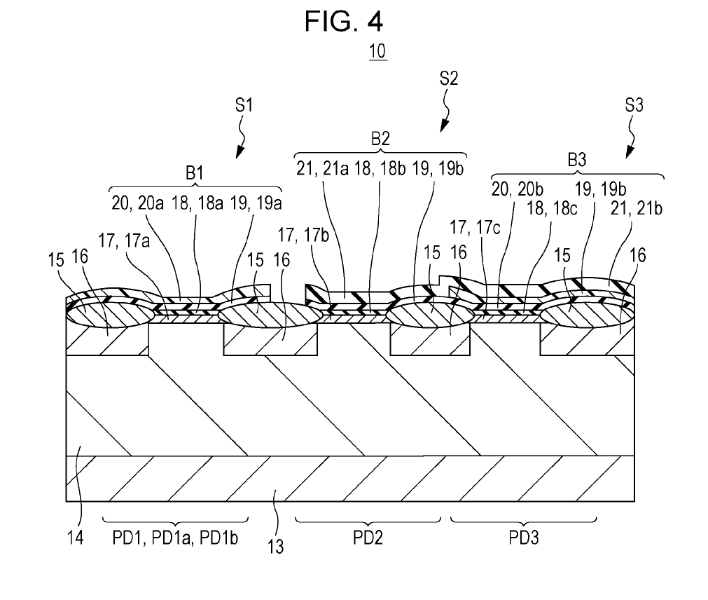

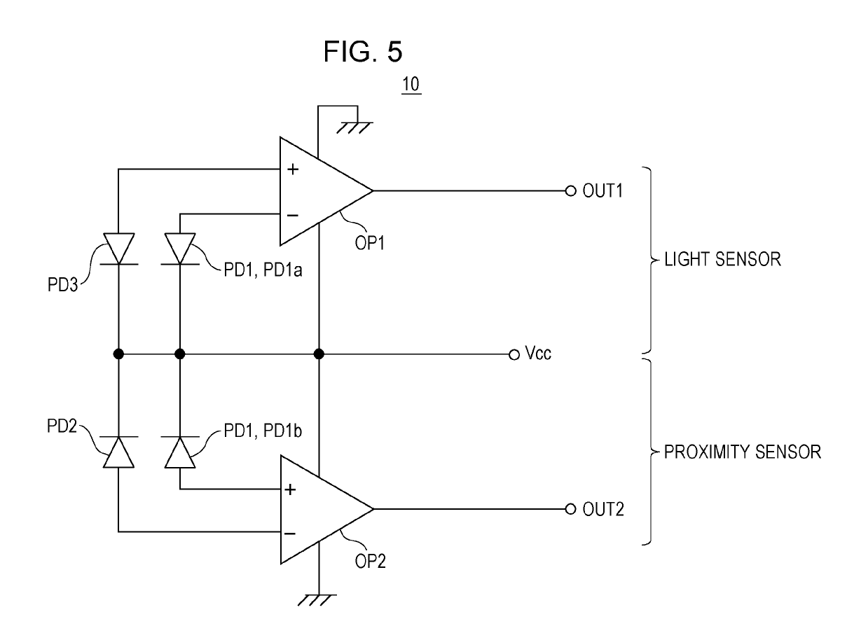

Hereinafter, the semiconductor device according to the embodiment will be described in detail with reference to the drawings. FIG. 4 is a schematic diagram illustrating a cross-sectional structure of the main parts of the semiconductor device 10 according to the embodiment, and FIG. 5 is a diagram illustrating a circuit configuration of the semiconductor device 10 according to the embodiment. In addition, in the embodiment, the semiconductor device 10 will be described using an example formed by a BiCMOS process where a bipolar junction transistor (BJT) is simultaneously formed during a CMOS process.

As shown in FIG. 4, the semiconductor device 10 includes the first photodiode PD1, the second photodiode PD2, and the third photodiode PD3 formed on the surface of, for example, the P type semiconductor substrate 13 such as a silicon (Si) substrate, doped with a P type impurity such as boron (B). In other words, each of the first photodiode PD1, the second photodiode PD2, and the third photodiode PD3 is formed of a high-resistive P type epitaxial layer 14, and an N type diffusion layer (cathode region) 17 formed on the surface of the P type epitaxial layer 14.

On the first photodiode PD1, that is, on the N type diffusion layer (cathode region) 17 (17a), the first laminated structure B1 including the silicon oxide film (first layer) 18 (18a), the silicon nitride film (second layer) 19 (19a), and the polysilicon film (third layer) 20 (20a), is formed. The first photodiode PD1 and the first laminated structure B1 form the first light sensing element S1.

In addition, on the second photodiode PD2, that is, on the N type diffusion layer (cathode region) 17 (17b), the second laminated structure B2 including the silicon oxide film (first layer) 18 (18b), the silicon nitride film (second layer) 19 (19b), and the polycrystalline silicon and germanium film (third layer) 21 (21a), is formed. The second photodiode PD2 and the second laminated structure B2 form the second light sensing element S2.

In addition, on the third photodiode PD3, that is, on the N type diffusion layer (cathode region) 17 (17c), the third laminated structure B3 including the silicon oxide film (first layer) 18 (18c), the silicon nitride film (second layer) 19 (19b), the polysilicon film (third layer) 20 (20b), and the polycrystalline silicon and germanium film (fourth layer) 21 (21b), is formed. The third photodiode PD3 and the third laminated structure B3 form the third light sensing element S3.

In the semiconductor device 10, P type diffusion layers 16 which are anode regions of the respective photodiodes PD1, PD2 and PD3 are formed in regions with the N type diffusion layers (cathode regions) 17 interposed therebetween in the P type epitaxial layer 14. In addition, element isolation oxide films 15 are formed on the P type diffusion layers 16, and the N type diffusion layers (cathode regions) 17 and the like are isolated from other elements by the element isolation oxide films 15.

Although not shown, the calculation circuits described later are formed on the P type semiconductor substrate 13, and the calculation circuits calculate (subtract) output results from the respective light sensing elements S1, S2 and S3.

In addition, although, in the embodiment, the silicon nitride film (second layer) 19 (19b) is commonly used in the second layer of the second laminated structure B2 and the second layer of the third laminated structure B3, the embodiment is not limited thereto, but, for example, a silicon nitride film as the second layer of the second laminated structure B2 and a silicon nitride film as the second layer of the third laminated structure B3 may be formed separately from each other. In addition, although, in the embodiment, the silicon oxide film as the first layer is formed for each of the light sensing elements S1, S2 and S3, the embodiment is not limited thereto, but the silicon oxide film may be commonly used as the first layer of the respective light sensing elements.

Next, a circuit configuration of the semiconductor device 10 according to the embodiment will be described with reference to FIG. 5. As shown in FIG. 5, the semiconductor device 10 includes the first photodiode PD1 (PD1a and PD1b), the second photodiode PD2, the third photodiode PD3, which are light sensing elements, and operational amplifiers OP1 and OP2 which are calculation elements.

The first photodiode PD1a has a cathode which is connected to a power supply voltage Vcc, and an anode which is connected to one input end (−) of the operational amplifier OP1. In addition, the third photodiode PD3 has a cathode which is connected to the power supply voltage Vcc and an anode which is connected to the other input end (+) of the operational amplifier OP1. In addition, an output end of the operational amplifier OP1 is connected to an output terminal OUT1. As such, the first photodiode PD1a, the third photodiode PD3, and the operational amplifier OP1 form the light sensor.

With the configuration of the light sensor, a signal corresponding to a light amount detected by the first photodiode PD1a and a signal corresponding to a light amount detected by the third photodiode PD3 are calculated by the operational amplifier OP1, and a calculated output is output from the output terminal OUT1.

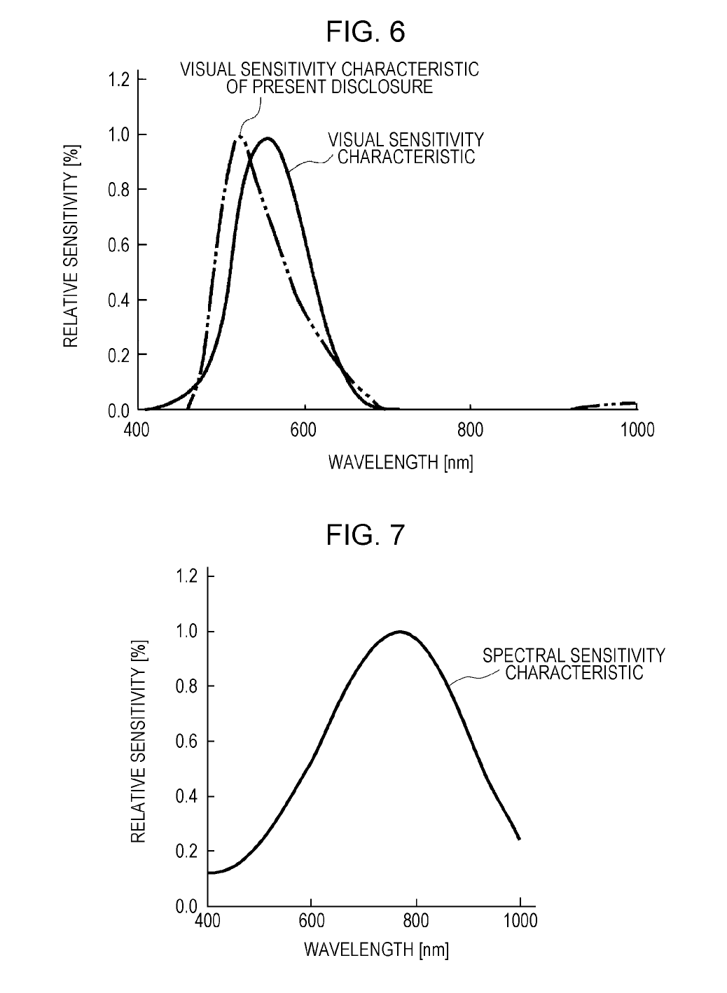

The calculated output which is output from the output terminal OUT1, that is, a spectral sensitivity characteristic of the light sensor has a peak around the wavelength 520 nm, as shown in FIG. 6, and is close to the visual sensitivity characteristic.

In addition, the first photodiode PD1b has a cathode which is connected to the power supply voltage Vcc and an anode which is connected to the other input end (+) of an operational amplifier OP2. The second photodiode PD2 has a cathode which is connected to the power supply voltage Vcc and an anode which is connected to one input end (−) of the operational amplifier OP2. In addition, an output end of the operational amplifier OP2 is connected to an output terminal OUT2. As such, the first photodiode PD1b, the second photodiode PD2, and the operational amplifier OP2 form the proximity sensor.

With the configuration of the proximity sensor, a signal corresponding to a light amount detected by the first photodiode PD1b and a signal corresponding to a light amount detected by the second photodiode PD2 are calculated by the operational amplifier OP2, and a calculated output is output from the output terminal OUT2.

The calculated output which is output from the output terminal OUT2, that is, a spectral sensitivity characteristic of the proximity sensor has a peak around the wavelength 780 nm, that is, the infrared range, as shown in FIG. 7.

3. Electronic Equipment to which Semiconductor Device According to First Embodiment is Applied

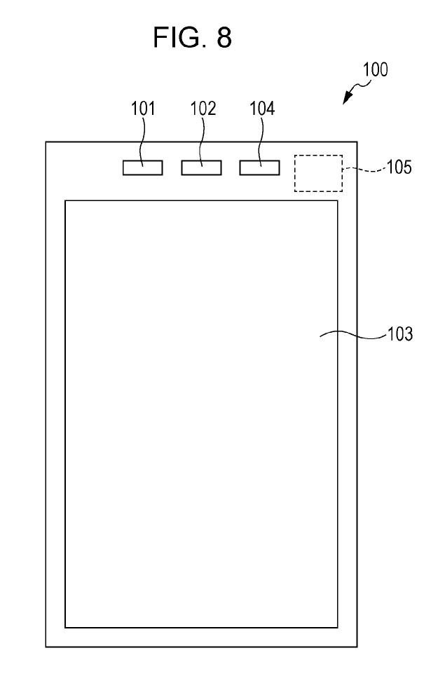

Next, electronic equipment 100 having the semiconductor device 10 according to the first embodiment will be described. The electronic equipment 100 is used as, for example, a PDA or a mobile phone, and, as shown in FIG. 8, includes a light sensor 101, a proximity sensor 102, a touch screen (corresponding to a “liquid crystal display panel” according to the embodiment of the present disclosure) 103, an LED 104 for the proximity sensor, and a control circuit 105 which controls detection signals of the light sensor and the proximity sensor.

The above-described semiconductor device 10 is applied as the light sensor 101 or the proximity sensor 102, and the luminance of a backlight of the touch screen 103 is adjusted depending on detection results thereof. Specifically, the control circuit 105 adjusts the luminance of the touch screen 103 based on a calculation result of the operational amplifier OP1 (refer to FIG. 5), and powers on and off the backlight of the touch screen 103 based on a calculation result of the operational amplifier OP2 (refer to FIG. 5).

In addition, the electronic equipment 100 is only an example, and the present disclosure is applicable to various kinds of electronic equipment having a liquid crystal display panel such as mobile phones, or various kinds of general electronic equipment such as panel lighting.

### 4. Manufacturing Method of Semiconductor Device

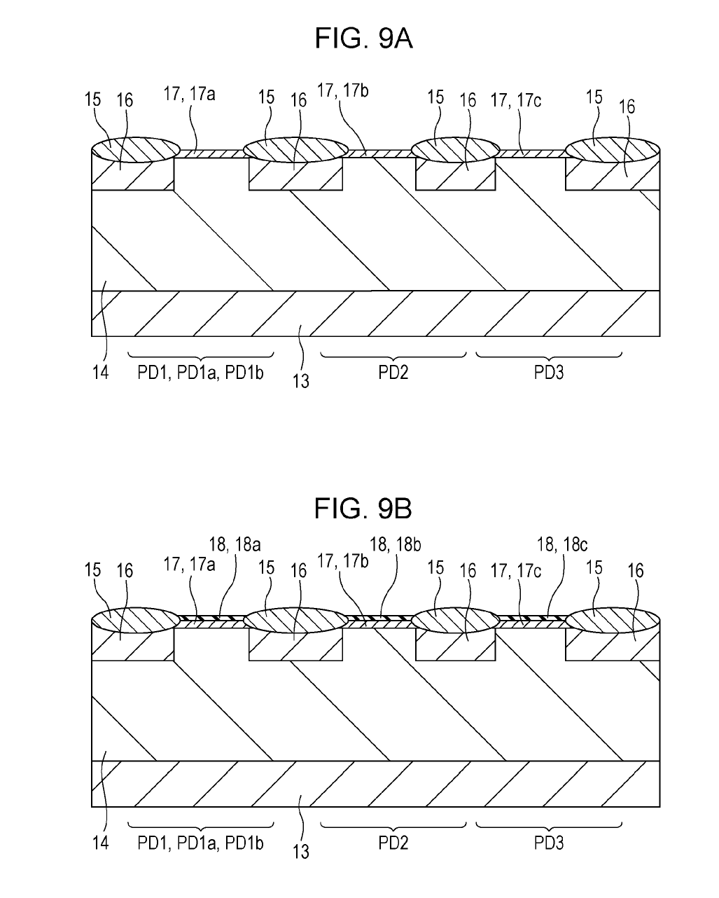

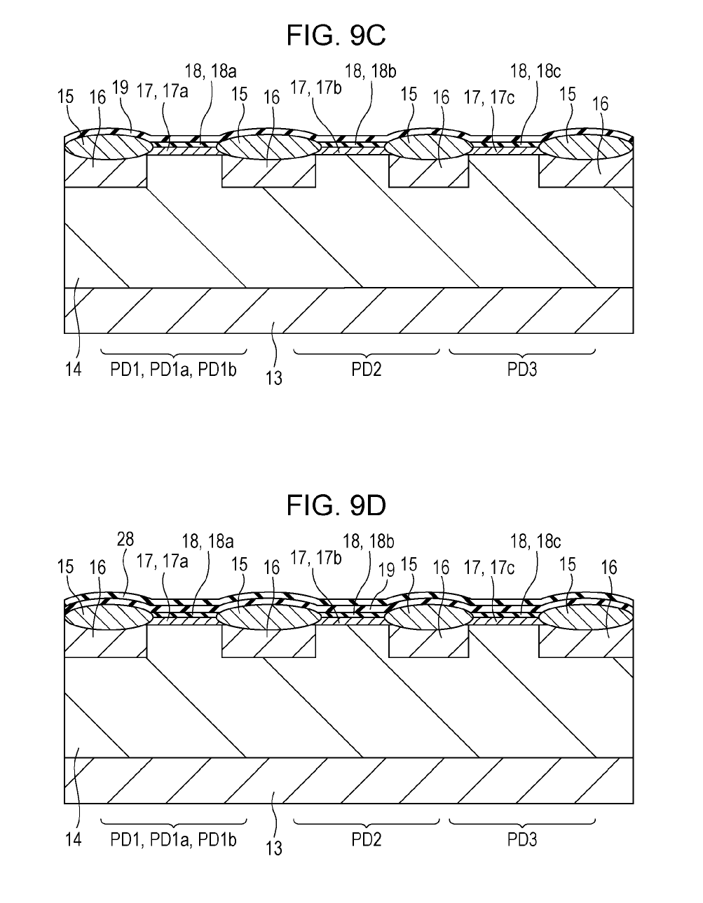

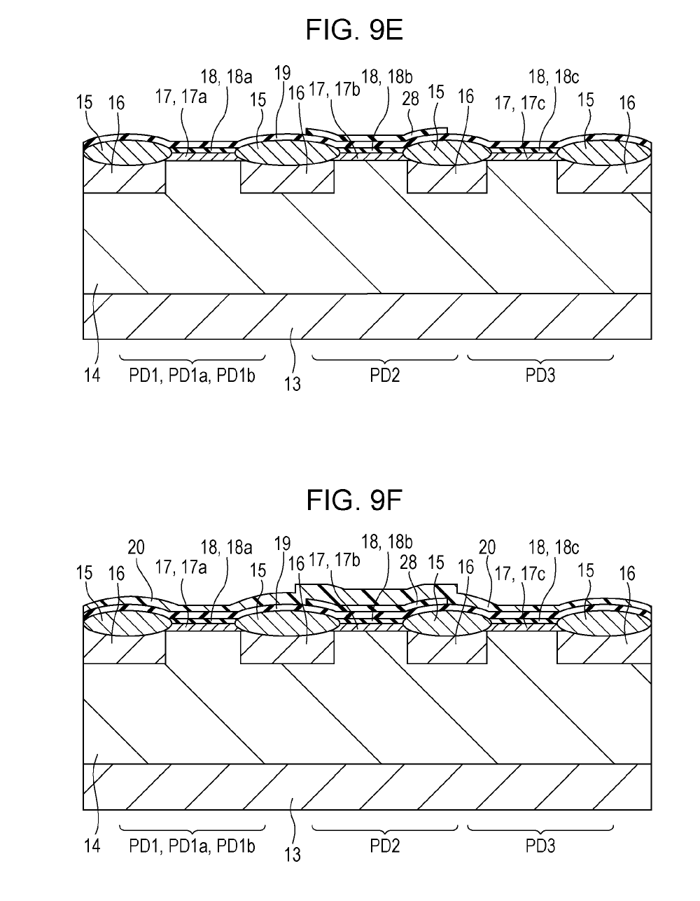

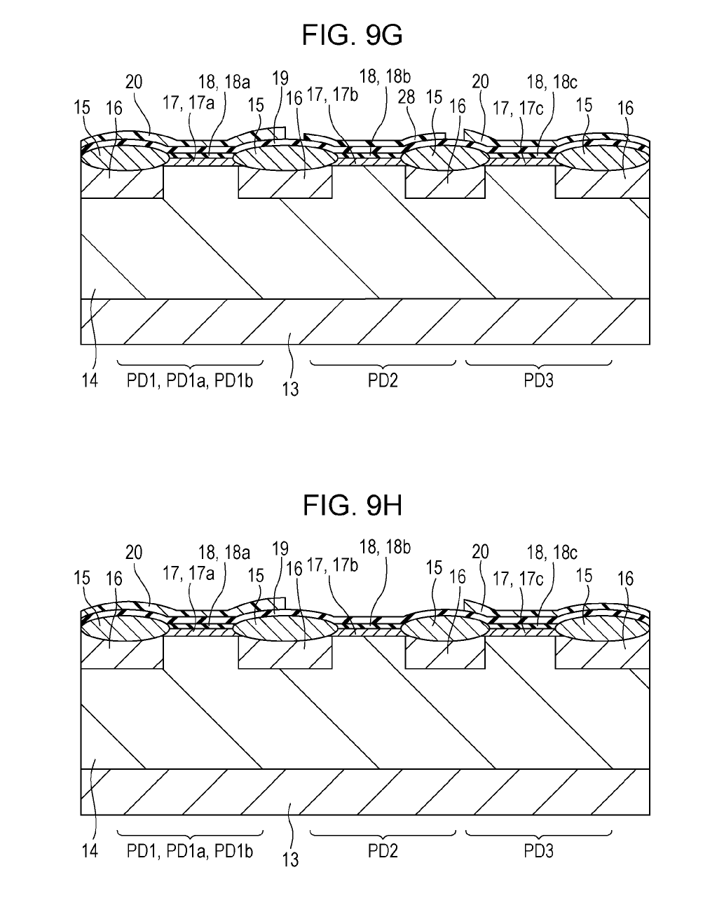

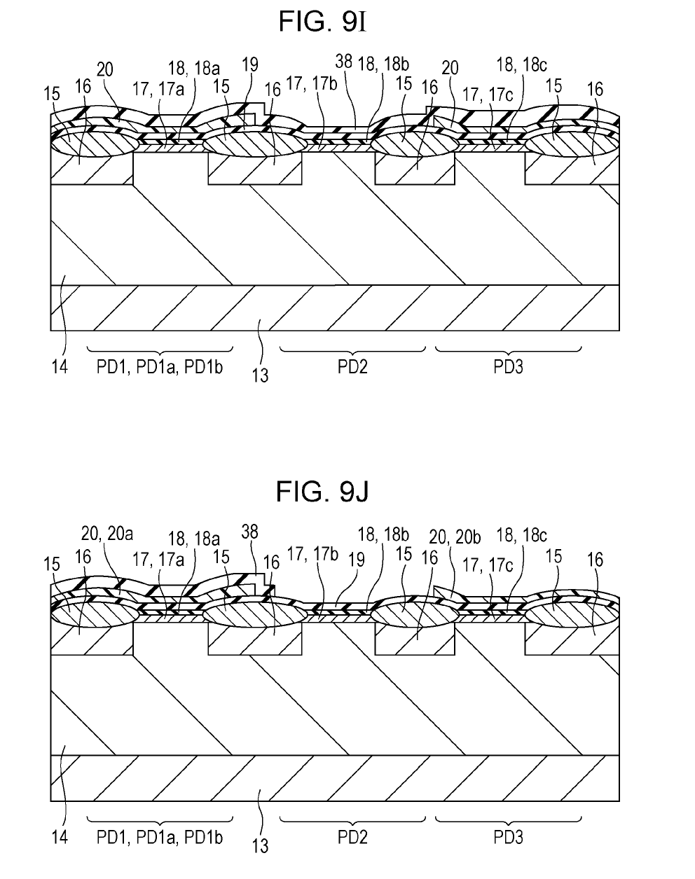

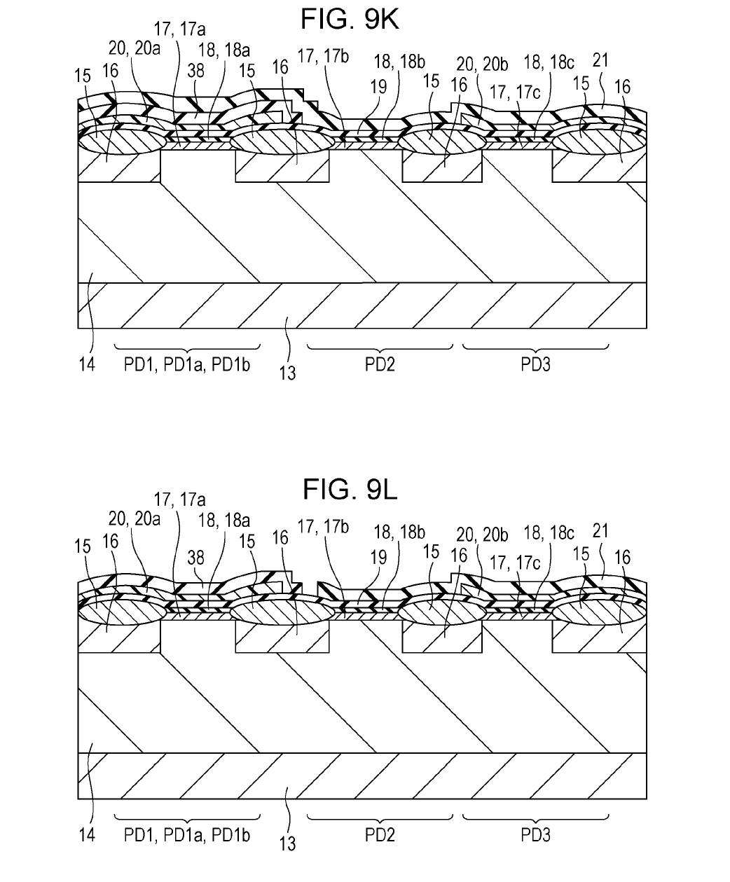

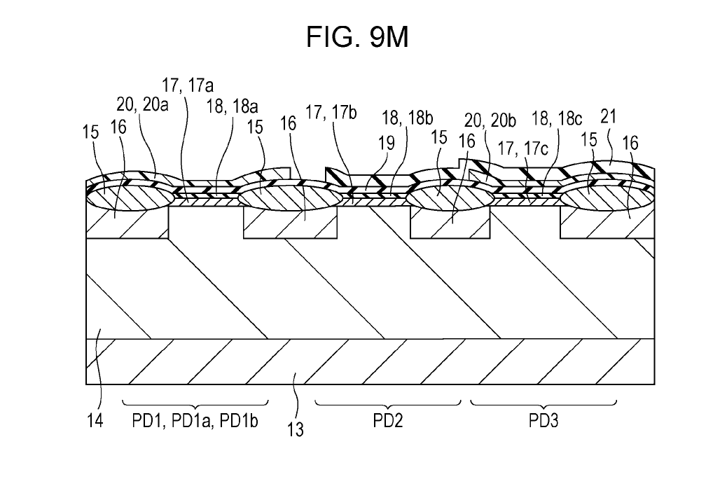

Next, a manufacturing method of the semiconductor device 10 according to the first embodiment will be described. FIGS. 9A to 9M are cross-sectional views illustrating manufacturing steps of the semiconductor device 10.

As shown in FIG. 9A, the first photodiode PD1, the second photodiode PD2, and the third photodiode PD3 are formed on a semiconductor substrate using the related art. Specifically, for example, the P type semiconductor substrate 13 obtained by doping a P type impurity such as boron (B) of concentration 1×10¹⁴ to 1×10¹⁶ atoms/cm³ in a silicon substrate is used as the semiconductor substrate of the semiconductor device 10.

In addition, a P type impurity such as boron (B) of concentration 1×10¹³ atoms/cm³ or more to 5×10¹⁴ atoms/cm³ or less is doped in the P type semiconductor substrate 13, and thereby the P type epitaxial layer 14 is deposited to have the film thickness 5 μm to 15 μm thereon. The P type epitaxial layer 14 is formed to have higher resistivity than the P type semiconductor substrate 13 by doping an impurity with concentration lower than that of the P type semiconductor substrate 13.

Next, the element isolation oxide films 15 are formed at predetermined positions by the LOCOS (Local Oxidation of Silicon) technique so as to isolate the photodiodes PD1, PD2 and PD3 from each other or other elements from each other.

Next, a resist film (not shown) is formed to cover the photodiodes PD1, PD2 and PD3 using a photolithography technique. Thereafter, an ion such as boron (B) is implanted into the P type epitaxial layer 14 excluding lower side where cathodes of the photodiodes PD1, PD2 and PD3 are formed, using the resist film.

Thereby, the P type diffusion layers 16 with the impurity concentration of 5×10¹⁴ atoms/cm³ or more to 1×10¹⁶ atoms/cm³ are formed.

Next, as shown in FIG. 9B, the silicon oxide films (first layer) 18 are formed on the N type diffusion layers (cathode regions) 17 using a CVD (Chemical Vapor Deposition) method or a thermal oxidation method. The film thickness of the silicon oxide film 18 preferably ranges, for example, from about 5 nm to 40 nm, and, more preferably, about 10 nm to 30 nm. In the embodiment, the film thickness of the silicon oxide film 18 is about 12 nm.

Next, as shown in FIG. 9C, the silicon nitride film 19 is formed on the silicon oxide films 18 and the element isolation oxide films 15 using the CVD method. The film thickness of the silicon nitride film 19 preferably ranges, for example, from about 10 nm to 60 nm, and, more preferably, from about 15 nm to 40 nm. In the embodiment, the film thickness of the silicon nitride film 19 is about 20 nm.

Next, as shown in FIG. 9D, the silicon oxide film 28 is formed on the silicon nitride film 19 using the CVD method, and, thereafter, as shown in FIG. 9E, the silicon oxide film 28 on the regions excluding the second photodiode PD2, that is, the silicon oxide film 28 on the first photodiode PD1 and the third photodiode PD3 is removed using the photolithography technique and an etching method.

Next, as shown in FIG. 9F, the polysilicon film 20 is formed on the silicon nitride film 19 and the silicon oxide film 28 using the CVD method. The film thickness of the polysilicon film 20 preferably ranges, for example, from about 20 nm to 100 nm, and, more preferably, from about 30 nm to 80 nm. In addition, in the embodiment, the film thickness of the polysilicon film 20 is about 33 nm.

Next, as shown in FIG. 9G, the polysilicon film 20 on the second photodiode PD2 is removed. In other words, the polysilicon film 20 at the upper part and the lateral parts of the silicon oxide film 28 is removed.

Next, as shown in FIG. 9H, the silicon oxide film 28 on the second photodiode PD2 is removed using the photolithography technique and the etching method.

Next, as shown in FIG. 9I, the silicon oxide film 38 is formed on the silicon nitride film (second layer) 19 and the polysilicon film (third layer) 20 using the CVD method. Next, as shown in FIG. 9J, the silicon oxide film 38 on the second photodiode PD2 and the third photodiode PD3 is removed using the photolithography technique and the etching method.

Thereafter, as shown in FIG. 9K, the polycrystalline silicon and germanium film 21 is formed on the silicon nitride film 19, the polysilicon film 20, and the silicon oxide film 38, using the CVD method. The film thickness of the polycrystalline silicon and germanium film 21 preferably ranges, for example, from about 20 nm to 120 nm, and, more preferably, from about 25 nm to 100 nm. In the embodiment, the film thickness of the silicon oxide film 38 is about 30 nm. In addition, the composition ratio of germanium in the polycrystalline silicon and germanium film 21 preferably ranges, for example, from about 35% to 55%, and, more preferably, from about 40% to 50%. In the embodiment, the composition ratio of germanium is about 39.7%.

Next, as shown in FIG. 9L, the polycrystalline silicon and germanium film 21 on the region excluding the second photodiode PD2 and the third photodiode PD3, that is, on the first photodiode PD1 is removed using the photolithography technique and the etching method. The polycrystalline silicon and germanium film 21 located between the second photodiode PD2 and the third photodiode PD3 are not necessarily connected to each other.

Next, as shown in FIG. 9M, the silicon oxide film 38 on the region excluding the second photodiode PD2 and the third photodiode PD3 is removed using the photolithography technique and the etching method. Thereafter, the silicon nitride film 19 on the region excluding the first photodiode PD1, the second photodiode PD2, and the third photodiode PD3 is removed using the photolithography technique and the etching method, thereby manufacturing the semiconductor device 10 shown in FIG. 4.

As such, according to the embodiment of the present disclosure, by calculating (subtracting) outputs from the first photodiode PD1, the second photodiode PD2, and the third photodiode PD3 where the composition ratio and the film thickness of the polycrystalline silicon and germanium film 21 are optimized, it is possible to simultaneously manufacture various sensors including a high sensitivity light sensor showing a characteristic close to the visual sensitivity characteristic.

Since a color filter is not used, a period for developing filter materials can be made unnecessary. For this reason, the number of components can be reduced, and thus development costs can be decreased.

Further, since the polycrystalline silicon and germanium film 21 is formed directly on the light sensing unit, even obliquely incident light can be detected with high efficiency, and thus variations in reflectance or attenuation amount of light can be reduced, thereby decreasing variations in the spectral sensitivity characteristic. Thereby, there is little difference in products, and a degree of freedom of a design can be improved by easily securing a characteristic close to a visual sensitivity characteristic.

### Second Embodiment

Next, a semiconductor device according to a second embodiment of the present disclosure will be described. The semiconductor device according to the embodiment includes a light sensor formed on a semiconductor substrate, and allows a spectral sensitivity characteristic to approach the visual sensitivity characteristic by optimizing a layer configuration of a laminated structure formed on a photodiode. The semiconductor device according to the embodiment will be described in detail with reference to the drawings. In addition, in the respective figures, the same constituent elements are given the same reference numerals. In addition, the description will be made in the following order.

1. LIGHT SENSING ELEMENT ACCORDING TO SECOND EMBODIMENT

2. SEMICONDUCTOR DEVICE ACCORDING TO SECOND EMBODIMENT

3. ELECTRONIC EQUIPMENT ACCORDING TO SECOND EMBODIMENT

4. MANUFACTURING METHOD OF SEMICONDUCTOR DEVICE ACCORDING TO SECOND EMBODIMENT

### 1. Light Sensing Element According to Second Embodiment

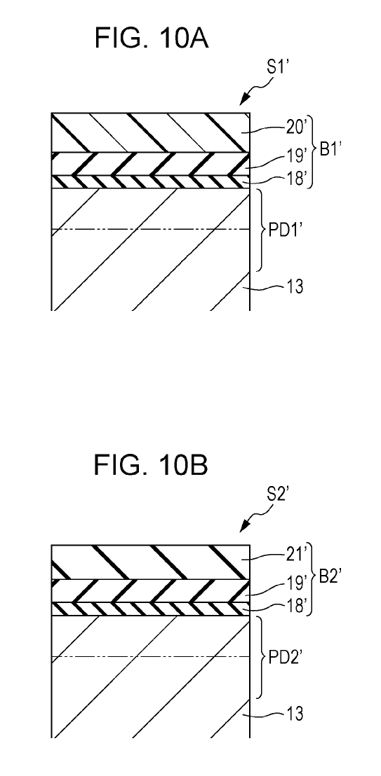

A light sensing element according to the embodiment includes a photodiode formed on a surface of a semiconductor substrate and a laminated structure formed on the photodiode and functioning as an optical filter, so as to obtain a desired optical characteristic in a manner similar to the above-described light sensing element according to the first embodiment. Hereinafter, the light sensing element according to the embodiment will be described with reference to the drawings. FIGS. 10A and 10B are diagrams illustrating cross-sectional configurations of laminated structures in the light sensing elements according to the embodiment. FIG. 10A is a diagram illustrating a configuration of a first light sensing element S1′, and FIG. 10B is a diagram illustrating a configuration of a second light sensing element S2′.

As shown in FIG. 10A, the first light sensing element S1′ includes a first photodiode PD1′ formed on a surface of, for example, a P type semiconductor substrate 13 such as silicon (Si), doped with a P type impurity such as boron (B), and a first laminated structure B1′ formed on the first photodiode PD1′.

The first laminated structure B1′ has a first layer 18′ formed on the first photodiode PD1′ and formed of a silicon oxide film, a second layer 19′ formed on the first layer 18′ and formed of a silicon nitride film, and a third layer 20′formed on the second layer 19′ and formed of a polysilicon film.

The film thickness of the silicon oxide film as the first layer 18′ is between, for example, 5 nm and 40 nm, and, preferably, between 10 nm and 30 nm. For example, in a case where the film thickness is 5 nm or less, there is a problem in that influence on photo-sensitivity increases by an amount corresponding to a difference in the film thickness. In addition, in a case where the film thickness is 40 nm or more, there is a problem in that spectral sensitivity controllability is deteriorated because interference with an overlying film or a multiple reflection effect increases. In the embodiment, the film thickness of the silicon oxide film as the first layer 18′ is 20 nm.

The film thickness of the silicon nitride film as the second layer 19′ is between, for example, 10 nm and 60 nm, and, preferably, between 15 nm and 40 nm. For example, in a case where the film thickness is 10 nm or less, there is a problem in that influence on photo-sensitivity increases by an amount corresponding to a difference in the film thickness. In addition, in a case where the film thickness is 60 nm or more, there is a problem in that spectral sensitivity controllability is deteriorated because interference with an overlying film or a multiple reflection effect increases. In the embodiment, the film thickness of the silicon nitride film as the second layer 19′ is 39.5 nm.

In addition, the film thickness of the polysilicon film as the third layer 20′ is between, for example, 20 nm and 100 nm, and, preferably, between 30 nm and 80 nm. For example, in a case where the film thickness is 20 nm or less, there is a problem in that uniformity of the film thickness is deteriorated, and the spectral sensitivity is irregular. In addition, in a case where the film thickness is 100 nm or more, there is a problem in that manufacturing costs increase. In the embodiment, the film thickness of the polysilicon film as the third layer 20′ is 80 nm.

Next, as shown in FIG. 10B, the second light sensing element S2′ includes a second photodiode PD2′ formed on the surface of the P type semiconductor substrate 13 and a second laminated structure B2′ formed on the second photodiode PD2′.

The second laminated structure B2′ has the first layer 18′ formed on the second photodiode PD2′ and formed of the silicon oxide film, the second layer 19′ formed on the first layer 18′ and formed of the silicon nitride film, and a third layer 21′ formed on the second layer 19′ and formed of a polycrystalline silicon and germanium film. The same configurations as the above-described first laminated structure B1′ are given the same reference numerals, and description thereof will be omitted.

The film thickness of the silicon oxide film as the third layer 21′ is, for example, between 20 nm and 120 nm, and, preferably, between 25 nm and 100 nm. As described above, in a case where the film thickness is 20 nm or less, there is a problem in that composition controllability of germanium is deteriorated, and the spectral sensitivity is irregular. In addition, in a case where the film thickness is 120 nm or more, there is a problem in that manufacturing costs increase. In the embodiment, the film thickness of the polycrystalline silicon and germanium film as the third layer 21′ is 75 nm.

Further, a composition ratio of germanium is between 35 to 55%. As described above, in a case where germanium is 35% or less, a value of the refractive index n and a value of the extinction coefficient k are little different from those in a case of using a polysilicon film on the uppermost layer of the laminated structure, and it is difficult to correct the spectral sensitivity. In addition, in a case where germanium is 55% or more, there is a problem in that surface roughness of the silicon and germanium film is deteriorated, which has influence on optical characteristics. In the embodiment, the composition ratio of germanium is 47.5%.

### 2. Semiconductor Device According to Second Embodiment

Next, the semiconductor device according to the embodiment will be described. The semiconductor device according to the embodiment includes the above-described light sensor. In the embodiment, the first laminated structure B1′ of the first light sensing element S1′ and the second laminated structure B2′ of the second light sensing element S2′ forming the light sensor have the above-described configuration, and thus the spectral sensitivity characteristic can approach the visual sensitivity characteristic.

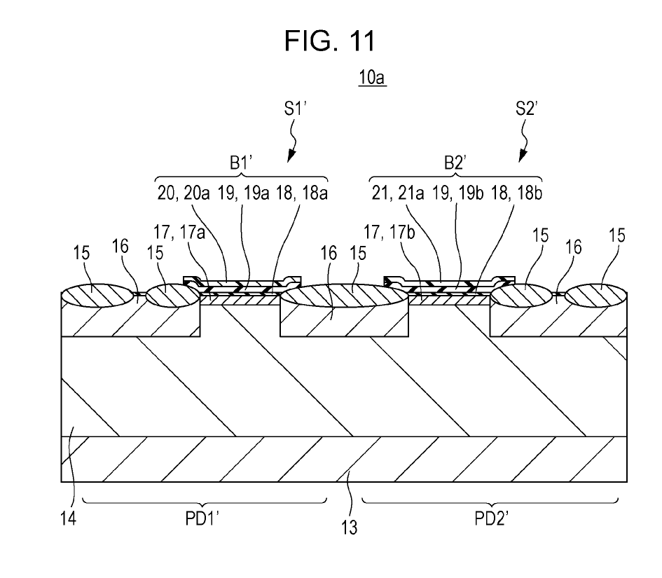

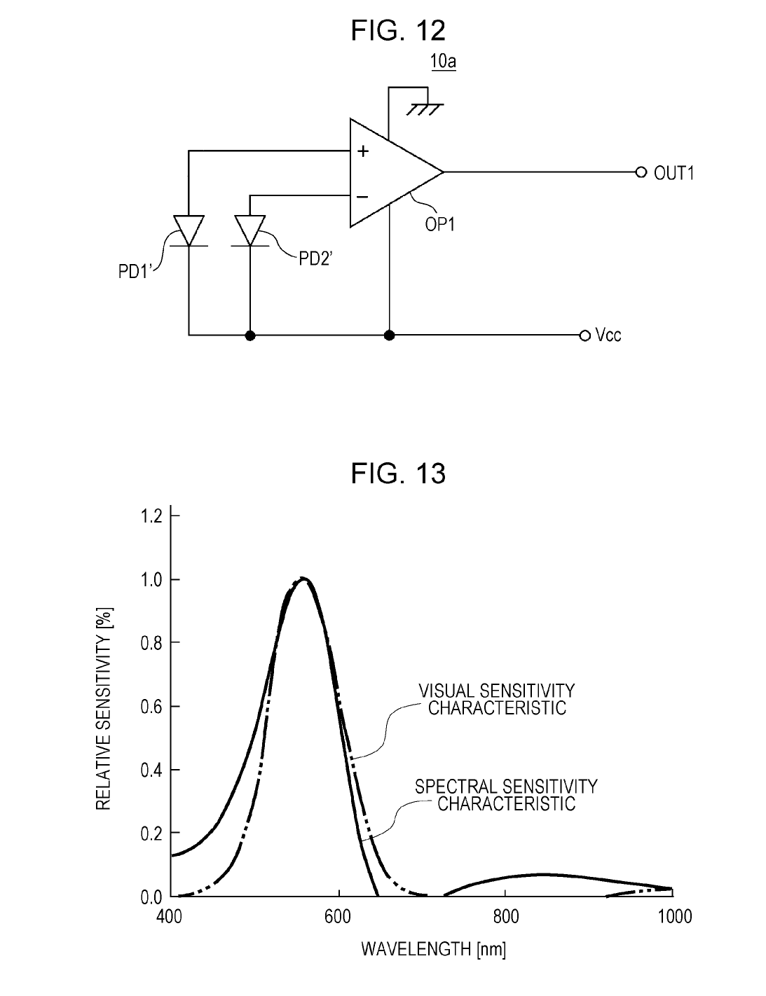

Hereinafter, the semiconductor device according to the embodiment will be described in detail with reference to the drawings. FIG. 11 is a schematic diagram illustrating a cross-sectional structure of the main parts of the semiconductor device 10a according to the embodiment, and FIG. 12 is a diagram illustrating a circuit configuration of the semiconductor device 10a according to the embodiment.

As shown in FIG. 11, the semiconductor device 10a includes the first photodiode PD1′ and the second photodiode PD2′ formed on the surface of, for example, the P type semiconductor substrate 13 such as silicon (Si) substrate, doped with a P type impurity such as boron (B). In other words, each of the first photodiode PD1′ and the second photodiode PD2′ is formed of a high-resistive P type epitaxial layer 14, and an N type diffusion layer (cathode region) 17 formed on the surface of the P type epitaxial layer 14.

On the first photodiode PD1′, that is, on the N type diffusion layer (cathode region) 17 (17a), the first laminated structure B1′ including the silicon oxide film (first layer) 18 (18a), the silicon nitride film (second layer) 19 (19a), and the polysilicon film (third layer) 20 (20a), is formed. The first photodiode PD1′ and the first laminated structure B1′ form the first light sensing element S1′.

In addition, on the second photodiode PD2′, that is, on the N type diffusion layer (cathode region) 17 (17b), the second laminated structure B2′ including the silicon oxide film (first layer) 18 (18b), the silicon nitride film (second layer) 19 (19b), and the polycrystalline silicon and germanium film (third layer) 21 (21a), is formed. The second photodiode PD2′ and the second laminated structure B2′ form the second light sensing element S2′.

In the semiconductor device 10a, P type diffusion layers 16 which are anode regions of the respective photodiodes PD1′ and PD2′ are formed in regions with the N type diffusion layers (cathode regions) 17 interposed therebetween in the P type epitaxial layer 14. In addition, element isolation oxide films 15 are formed on the P type diffusion layers 16, and the N type diffusion layers (cathode regions) 17 and the like are isolated from other elements by the element isolation oxide films 15.

Although not shown, the calculation circuits described later are formed on the P type semiconductor substrate 13 in a manner similar to the semiconductor device 10, and the calculation circuits calculate (subtract) output results from the respective light sensing elements S1′ and S2′.

In addition, although, in the embodiment, for example, the silicon oxide film as the first layer is formed for each of the light sensing elements S1′ and S2′, the embodiment is not limited thereto, but the silicon oxide film may be commonly used as the first layer of the respective light sensing elements.

Next, a circuit configuration of the semiconductor device 10a according to the embodiment will be described with reference to FIG. 12. As shown in FIG. 12, the semiconductor device 10a includes the first photodiode PD1′ and the second photodiode PD2′ which are light sensing elements, and an operational amplifier OP1 which is a calculation element.

The first photodiode PD1′ has a cathode which is connected to a power supply voltage Vcc, and an anode which is connected to one input end (−) of the operational amplifier OP1. In addition, the second photodiode PD2′ has a cathode which is connected to the power supply voltage Vcc and an anode which is connected to the other end (+) of the operational amplifier OP1. In addition, an output end of the operational amplifier OP1 is connected to an output terminal OUT1. As such, the first photodiode PD1′, the second photodiode PD2′, and the operational amplifier OP1 form the light sensor.

With the configuration of the light sensor, a signal corresponding to a light amount detected by the first photodiode PD1′ and a signal corresponding to a light amount detected by the second photodiode PD2′ are calculated by the operational amplifier OP1, and a calculated output is output from the output terminal OUT1.

The calculated output which is output from the output terminal OUT1, that is, a spectral sensitivity characteristic of the light sensor is closer to the visual sensitivity characteristic than the spectral sensitivity characteristic of the light sensor of the semiconductor device 10, as shown in FIG. 13.

3. Electronic Equipment to which Semiconductor Device According to Second Embodiment is Applied

Next, electronic equipment 100 having the semiconductor device 10a according to the second embodiment will be described. The electronic equipment 100 is used as, for example, a PDA or a mobile phone, and, as shown in FIG. 8, includes a light sensor 101, a proximity sensor 102, a touch screen 103, an LED 104 for the proximity sensor, and a control circuit 105 which controls detection signals of the light sensor and the proximity sensor.

The above-described semiconductor device 10a is applied as the light sensor 101 or the proximity sensor 102, and the luminance of a backlight of the touch screen 103 is adjusted depending on detection results thereof. Specifically, the control circuit 105 adjusts the luminance based on a calculation result of the operational amplifier.

In addition, the electronic equipment 100 is only an example, and the present disclosure is applicable to various kinds of electronic equipment having a liquid crystal display panel such as mobile phones, or various kinds of general electronic equipment such as panel lighting.

### 4. Manufacturing Method of Semiconductor Device

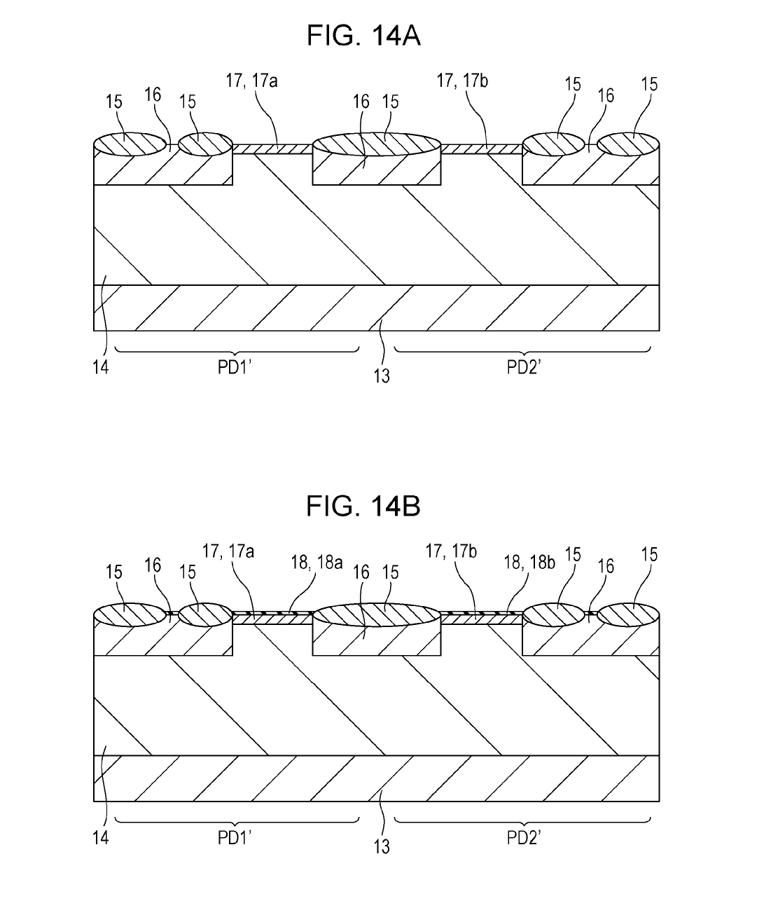

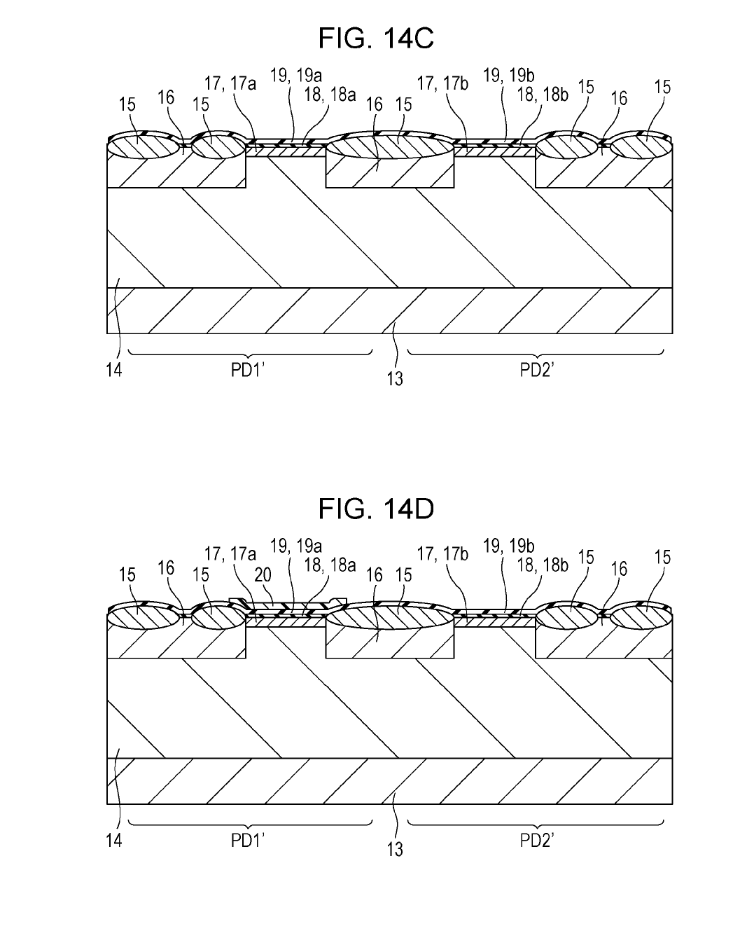

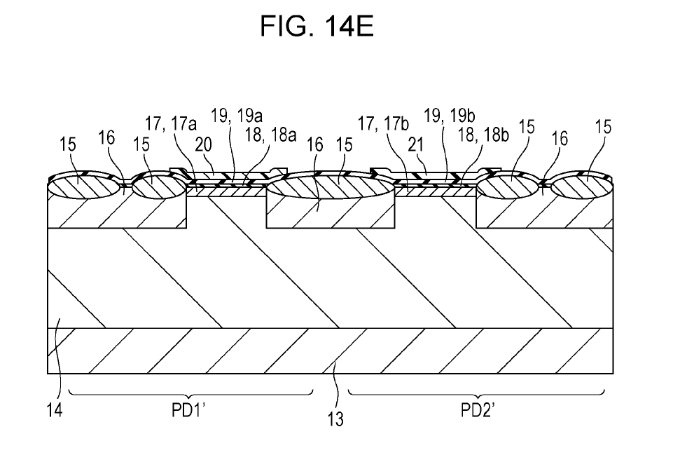

Next, a manufacturing method of the semiconductor device 10a according to the embodiment will be described. FIGS. 14A to 14E are cross-sectional views illustrating a manufacturing process of the semiconductor device 10a.

As shown in FIG. 14A, the first photodiode PD1′, the second photodiode PD2′, and the element isolation oxide films 15 isolating the photodiodes PD1′ and PD2′ from each other are formed on a semiconductor substrate using the related art. In addition, this step is the same as the step shown in FIG. 9A, and thus description thereof will be omitted.

Next, as shown in FIG. 14B, the silicon oxide films (first layer) 18 are formed on the N type diffusion layers (cathode regions) 17 using a CVD method or a thermal oxidation method. The film thickness of the silicon oxide film 18 preferably ranges, for example, from about 5 nm to 40 nm, and, more preferably, about 10 nm to 30 nm. In the embodiment, the film thickness of the silicon oxide film 18 is about 20 nm.

Next, as shown in FIG. 14C, the silicon nitride film 19 is formed on the silicon oxide films 18 and the element isolation oxide films 15 using the CVD method. The film thickness of the silicon nitride film 19 preferably ranges, for example, from about 10 nm to 60 nm, and, more preferably, from about 15 nm to 40 nm. In the embodiment, the film thickness of the silicon nitride film 19 is about 39.5 nm.

Next, in the same manner as in FIGS. 9D and 9E of the first embodiment, a silicon oxide film (not shown on the second photodiode PD2′) is formed on the silicon nitride film 19 using the CVD method, and, thereafter, the silicon oxide film on the region excluding the second photodiode PD2′, that is, the silicon oxide film on the first photodiode PD1′ is removed using the photolithography technique and an etching method.

Next, as shown in FIG. 14D, the polysilicon film 20 is formed over the N type diffusion layer (cathode region) 17 of the first photodiode PD1′ on the silicon nitride film 19 using the CVD method and the etching method. The film thickness of the polysilicon film 20 preferably ranges, for example, from about 20 nm to 100 nm, and, more preferably, from about 30 nm to 80 nm. In addition, in the embodiment, the film thickness of the polysilicon film 20 is about 80 nm.

Next, in the same manner as in FIGS. 9I and 9J of the first embodiment, a silicon oxide film (not shown on the first photodiode PD1′) is formed on the polysilicon film 20 using the CVD method, and, thereafter, the silicon oxide film on the region excluding the first photodiode PD1′, that is, the silicon oxide film on the second photodiode PD2′ is removed using the photolithography technique and an etching method.

Thereafter, as shown in FIG. 14E, the polycrystalline silicon and germanium film 21 is formed over the N type diffusion layer (cathode region) 17 (17b) of the second photodiode PD2′ on the silicon nitride film 19, using the CVD method and the etching method. The film thickness of the polycrystalline silicon and germanium film 21 preferably ranges, for example, from about 20 nm to 120 nm, and, more preferably, from about 25 nm to 100 nm. In the embodiment, the film thickness of the polycrystalline silicon and germanium film 21 is about 75 nm. In addition, the composition ratio of germanium in the polycrystalline silicon and germanium film 21 preferably ranges, for example, from about 35% to 55%, and, more preferably, from about 40% to 50%. In the embodiment, the composition ratio of germanium is about 47.5%.

Next, although not shown, in the same manner as in FIGS. 9L and 9M of the first embodiment, only the polycrystalline silicon and germanium film 21 formed over the first photodiode PD1′ and the underlying silicon oxide film are removed using the photolithography technique and the etching method, thereby exposing the polysilicon film 20.

As such, according to the manufacturing method of the semiconductor device according to the embodiment, by calculating (subtracting) outputs from the first photodiode PD1′ and the second photodiode PD2′ where the composition ratio (the content of germanium) and the film thickness of the polycrystalline silicon and germanium film 21 are optimized, it is possible to manufacture the semiconductor device 10a as a light sensor having a spectral sensitivity characteristic closer to the visual sensitivity characteristic.

Since a color filter described in the related art is not used, a period for developing filter materials can be made unnecessary. For this reason, the number of components can be reduced, and thus development costs can be decreased.

Further, since the polycrystalline silicon and germanium film 21 is formed directly on the light sensing unit, even obliquely incident light can be detected with high efficiency, and thus variations in reflectance or attenuation amount of light can be reduced, thereby decreasing variations in the spectral sensitivity characteristic. Thereby, there is little difference in products, and a degree of freedom of a design can be improved by easily securing a spectral sensitivity characteristic having a peak value in an infrared region.

The present disclosure contains subject matter related to that disclosed in Japanese Priority Patent Application JP 2010-225011 filed in the Japan Patent Office on Oct. 4, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light sensing element comprising:
a photodiode formed on a semiconductor substrate surface; and
a laminated structure formed on the photodiode, wherein the laminated structure includes
a first layer formed of a silicon oxide film;
a second layer formed on the first layer and formed of a silicon nitride film; and
a third layer formed on the second layer and formed of a polysilicon film.

2. The light sensing element according to claim 1, wherein the laminated structure further includes a fourth layer formed on the third layer and formed of a polycrystalline silicon and germanium film.

3. A light sensing element comprising:
a photodiode formed on a semiconductor substrate surface; and
a laminated structure formed on the photodiode,
wherein the laminated structure includes
a first layer formed of a silicon oxide film;
a second layer formed on the first layer and formed of a silicon nitride film; and
a third layer formed on the second layer and formed of a polycrystalline silicon and germanium film.

4. A semiconductor device comprising:
a first photodiode, a second photodiode, and a third photodiode, formed on a semiconductor substrate surface;
a first laminated structure formed on the first photodiode;
a second laminated structure formed on the second photodiode;
a third laminated structure formed on the third photodiode;
a first calculation circuit calculating a difference between outputs from the first photodiode and the third photodiode; and
a second calculation circuit calculating a difference between outputs from the first photodiode and the second photodiode,
wherein the first laminated structure includes
a first layer formed of a silicon oxide film;
a second layer formed on the first layer and formed of a silicon nitride film; and
a third layer formed on the second layer and formed of a polysilicon film,
wherein the second laminated structure includes
a first layer formed of the silicon oxide film;
a second layer formed on the first layer and formed of the silicon nitride film; and
a third layer formed on the second layer and formed of a polycrystalline silicon and germanium film, and
wherein the third laminated structure includes
a first layer formed of a silicon oxide film;
a second layer formed on the first layer and formed of a silicon nitride film;
a third layer formed on the second layer and formed of the polysilicon film; and
a fourth layer formed on the third layer formed of the polysilicon film and formed of the polycrystalline silicon and germanium film.

5. A semiconductor device comprising:
a first photodiode and a second photodiode formed on a semiconductor substrate surface;
a first laminated structure formed on the first photodiode;
a second laminated structure formed on the second photodiode; and
a calculation circuit calculating a difference between outputs from the first photodiode and the second photodiode,
wherein the first laminated structure includes
a first layer formed of a silicon oxide film;
a second layer formed on the first layer and formed of a silicon nitride film; and
a third layer formed on the second layer and formed of a polysilicon film, and
wherein the second laminated structure includes
a first layer formed of the silicon oxide film;
a second layer formed on the first layer and formed of the silicon nitride film; and
a third layer formed on the second layer and formed of a polycrystalline silicon and germanium film.

6. Electronic equipment comprising:
a first photodiode, a second photodiode, and a third photodiode, formed on a semiconductor substrate surface;
a first laminated structure formed on the first photodiode;
a second laminated structure formed on the second photodiode;
a third laminated structure formed on the third photodiode;
a first calculation circuit calculating a difference between outputs from the first photodiode and the third photodiode;
a second calculation circuit calculating a difference between outputs from the first photodiode and the second photodiode;
a liquid crystal display panel; and
a control circuit adjusting luminance of the liquid crystal display panel based on a calculation result of the first calculation circuit, and powering on and off a backlight of the liquid crystal display panel based on a calculation result of the second calculation circuit,
wherein the first laminated structure includes
a first layer formed of a silicon oxide film;
a second layer formed on the first layer and formed of a silicon nitride film; and
a third layer formed on the second layer and formed of a polysilicon film,
wherein the second laminated structure includes
a first layer formed of the silicon oxide film;
a second layer formed on the first layer and formed of the silicon nitride film; and
a third layer formed on the second layer and formed of a polycrystalline silicon and germanium film, and
wherein the third laminated structure includes
a first layer formed of the silicon oxide film;
a second layer formed on the first layer and formed of the silicon nitride film;
a third layer formed on the second layer and formed of the polysilicon film; and
a fourth layer formed on the third layer and formed of the polycrystalline silicon and germanium film.

7. Electronic equipment comprising:
a first photodiode and a second photodiode formed on a semiconductor substrate surface;
a first laminated structure formed on the first photodiode;
a second laminated structure formed on the second photodiode;
a calculation circuit calculating a difference between outputs from the first photodiode and the second photodiode;
a liquid crystal display panel; and
a control circuit adjusting luminance of the liquid crystal display panel based on a calculation result of the calculation circuit,
wherein the first laminated structure includes
a first layer formed of a silicon oxide film;
a second layer formed on the first layer and formed of a silicon nitride film; and
a third layer formed on the second layer and formed of a polysilicon film, and
wherein the second laminated structure includes
a first layer formed of the silicon oxide film;
a second layer formed on the first layer and formed of the silicon nitride film; and
a third layer formed on the second layer and formed of a polycrystalline silicon and germanium film.

8. A manufacturing method of a light sensing element comprising:
forming a photodiode on a semiconductor substrate;
forming a silicon oxide film on the photodiode;
forming a silicon nitride film on the silicon oxide film; and
forming a polysilicon film on the silicon nitride film.

9. The manufacturing method of the light sensing element according to claim 8, further comprising forming a polycrystalline silicon and germanium film on the polysilicon film.

10. A manufacturing method of a light sensing element comprising:
forming a photodiode on a semiconductor substrate;
forming a silicon oxide film on the photodiode;
forming a silicon nitride film on the silicon oxide film; and
forming a polycrystalline silicon and germanium film on the silicon nitride film.

11. A manufacturing method of a semiconductor device comprising:
forming a first photodiode, a second photodiode, and a third photodiode on a semiconductor substrate;
forming a silicon oxide film on the first photodiode, the second photodiode, and the third photodiode;
forming a silicon nitride film on the silicon oxide film;
forming a polysilicon film on the silicon nitride film of the first photodiode and the third photodiode; and
forming a polycrystalline silicon and germanium film on the polysilicon film of the third photodiode and forming the polycrystalline silicon and germanium film on the silicon nitride film of the second photodiode.

12. A manufacturing method of a semiconductor device comprising:
forming a first photodiode and a second photodiode on a semiconductor substrate;
forming a silicon oxide film on the first photodiode and the second photodiode;
forming a silicon nitride film on the silicon oxide film;
forming a polysilicon film on the silicon nitride film of the first photodiode; and
forming a polycrystalline silicon and germanium film on the silicon nitride film of the second photodiode.
